(19) United States
(12) Patent Application Publication
(10) Pub. No.: US 2009/0085697 A1
(43) Pub. Date: Apr. 2, 2009

(54) METHOD AND APPARATUS FOR ANALOG VALIDATION OF HIGH SPEED BUSES USING ELECTROMAGNETIC COUPLERS

(76) Inventors: Todd Hinck, Arlington, MA (US); Larry Tate, Hopkinton, MA (US); John Benham, Hopkinton, MA (US); John Critchlow, Northborough, MA (US)

Correspondence Address: INTEL CORPORATION;c/o INTELLEVATE, LLC, P.O. BOX 52050, MINNEAPOLIS, MN, 55402, US

(21) Appl. No.: 11/862,332

(22) Filed: Sep. 27, 2007

(51) Int. Cl. H03H 2/00

(52) U.S. Cl. 333/24 R

(57) ABSTRACT

In at least one embodiment an apparatus is provided that includes an electromagnetic coupler to provide sampled electromagnetic signals and an electronics component to receive the sampled electromagnetic signals from the electromagnetic coupler, to amplify and recover a derivative-like output signal, and to provide recovered sampled electromagnetic signals to an oscilloscope with a unity transfer function. Other embodiments may be described and claimed.

### FIELD

Embodiments of the present invention may relate to the field of electromagnetic probing, and more specifically to a method and apparatus for analog validation of high speed buses using electromagnetic couplers.

### BACKGROUND

The probing of input/output (I/O) buses has been done using various direct-attached methodologies. Example methodologies may include resistive-based probe technology connected to an oscilloscope or a logic analyzer. However, as bus speeds scale to higher data rates, traditional direct-attach probing may cause signal integrity issues for a link under test (LUT).

### BRIEF DESCRIPTION OF THE DRAWINGS

Embodiments of the present invention may become apparent from the following detailed description of arrangements, example embodiments, and the claims when read in connection with the accompanying drawings. While the foregoing and following written and illustrated disclosure focuses on disclosing arrangements and example embodiments of the invention, it should be clearly understood that the same is by way of illustration and example only and embodiments of the invention are not limited thereto.

The following represents brief descriptions of the drawings in which like reference numerals represent like elements and wherein:

FIG. 1 is a block diagram of an example system for analog validation of high speed buses using electromagnetic couplers, in accordance with one example embodiment of the invention;

FIG. 2 is a block diagram of an example electronics component solution for analog validation of high speed buses using electromagnetic couplers, in accordance with one example embodiment of the invention; and

FIG. 3 is a block diagram of an example electronic appliance suitable for implementing analog validation of high speed buses using electromagnetic couplers, in accordance with one example embodiment of the invention.

### DETAILED DESCRIPTION

In the detailed description to follow, example sizes/models/values/ranges may be given with reference to embodiments of the present invention. Other embodiments may also be used. Where specific details are set forth in order to describe example embodiments of the invention, it should be apparent to one skilled in the art that the invention can be practiced without these specific details.

In the following discussion, the terminology coupler probe and coupler may be used. These terminologies are intended to be interchangeable. Additionally, various devices may be referred to as first, second and/or third devices. The use of the terms first, second, and/or third is merely a label and is not intended to identify a specific location of a device with respect to other devices.

Embodiments of the present invention may provide an electronics component for a direct-attached electromagnetic (EM) coupler probe (or coupler). An EM coupler probe (such as a direct-attached EM coupler probe) samples a link under test (LUT) using crosstalk coupled from signals on the LUT. The sampled signals are used to recover the analog signals that are present on the LUT. In one embodiment, this is accomplished using an electronics receiver component (hereafter also called an electronics component). The coupler probe outputs a derivative-like signal of the LUT signal. The LUT output signal is recovered by integrating the signal. An integration function is an inverse of a derivative function, so a baseband signal gets restored albeit in a scaled form. In one embodiment, amplification and a unity transfer function are included to provide a close approximation of the LUT signal. Embodiments of the present invention may provide probing for signaling validation or logical debug using an analyzing device.

FIG. 1 is a block diagram of an example system for analog validation of high speed buses using electromagnetic couplers, in accordance with one example embodiment of the invention. Other embodiments and configurations may also be used. FIG. 1 shows a transmitting device 102 and a receiving device 104 coupled by a LUT 106. The terminology LUT refers to at least one signal connection between the transmitting device 102 and the receiving device 104. Although the terminology LUT is used hereafter, the transmitting device 102 and the receiving device 104 may be coupled by a bus, an interconnect, signal lines, printed circuit board (pcb) traces, flex cables, micro-coax, and/or other electrical connection means.

The transmitting device 102 may include a data generating device to generate a data pattern, for example, to be transmitted on the LUT 106 to the receiving device 104. The data waveform may be differential DC encoded data or the data waveform may be differential non-DC encoded data. The transmitting device 102 may be provided on one chip and the receiving device 104 may be provided on another chip such that at least the LUT 106 is connected between the two chips to enable a data waveform to be transmitted between the two chips. The data waveform may be transmitted and/or validated during a validation process of a product (that includes at least one of the two chips), during a debugging of a product (that includes at least one of the two chips) and/or during actual use of the product (that includes at least one of the two chips).

System 100 shown in FIG. 1 may include an EM coupler 108 coupled to the LUT 106 and an electronics component 110 connected to the EM coupler 108. These may be connected using micro-coax, printed circuit board (pcb) traces, flex cables, and/or other electrical connection means. The EM coupler 108 may provide sampled electromagnetic signals. The electronics component 110 may receive the sampled electromagnetic signals from the EM coupler 108 based on the data (or data patterns) transmitted on the LUT 106. The electronics component 110 may provide recovered sampled electromagnetic signals.

As one example, the EM coupler 108 may include two parallel signal traces provided for each differential pair of traces of the LUT 106. The EM coupler 108 may be coupled to the LUT 106, such as directly-coupled. Additionally, the EM coupler 108 may be alternating current (AC) coupled to the LUT 106 by having both inductive and capacitive coupling. As one example, the coupler probe strength, a measure of the coupled signal to the LUT signal, may be set between 0.1<K_{c}<0.2, where Kc is defined as a coupling coefficient (i.e., a ratio of coupler output voltage to the LUT voltage at an input to the coupler probe) to remove approximately 1% to 4% of the LUT signal power. Other examples of the EM coupler 108 are also within the scope of the present invention.

The electronics component 110 of system 100 may perform signal processing to obtain recovered electromagnetic signals that may be used to validate or invalidate the baseband signals transmitted on the LUT 106. The signals on the LUT 106 may be Binary No Return to Zero (BNRZ) data, 8B10B data or 64B66B data, for example. Other types of data may also be used.

Stated differently, the electronics component 110 may provide recovered electromagnetic signals. Inputs and outputs of the electronics component 110 may be differential. Output signals of the electronics component 110 may be provided to analyzing device 112 to validate or invalidate baseband signals transmitted on the LUT. Analyzing device 112 may be an oscilloscope, or other apparatus to analyze the recovered data. Accordingly, the electronics component 110 performs signal processing to the received electromagnetic signals to allow analog signals corresponding to the recovered sampled signals to be validated.

In one embodiment, to provide a near approximation of signals transmitted along LUT 106, electronics component 110 may amplify and integrate the output from EM coupler 108 and provide the recovered signals to analyzing device 112 with a unity transfer function. In one embodiment, electronics component 110 has a sufficient bandwidth to transport the baseband signals.

Analyzing device 112 may include digital signal processing capability 114. In one embodiment, analyzing device 112 may have the capability to measure and monitor the incoming EM recovered signal and also to filter any RMS jitter caused by electronics component 110. In one embodiment, functions described herein as being performed by electronics component 110 may be wholly or partly implemented through a configuration of digital signal processing capability 114. In other words, digital signal processing capability 114 may be programmed to transform the output of EM coupler 108 with an integrator-like transfer function and with equalization techniques.

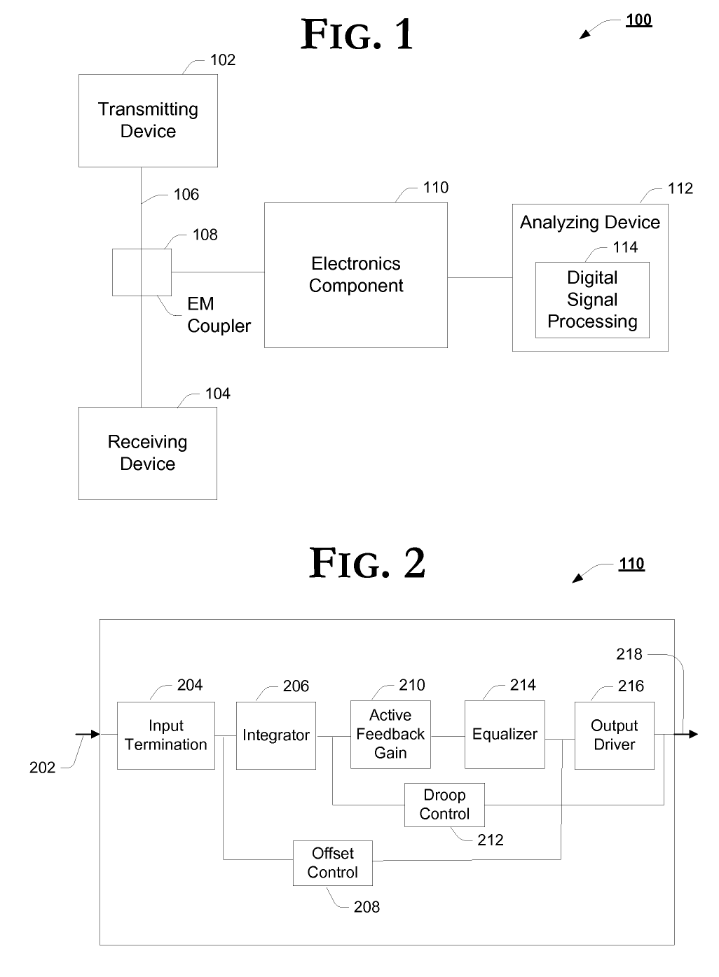

FIG. 2 is a block diagram of an example electronics component solution for analog validation of high speed buses using electromagnetic couplers, in accordance with one example embodiment of the invention. Electronics component 110 may include input 202, input termination 204, integrator 206, offset control 208, active feedback gain 210, droop control 212, equalizer 214, output driver 216 and output 218, as shown. Input 202 represents a transport of the sampled signals from EM coupler 108 to input termination 204, which may provide impedance matching.

In this example, integrator 206 may be considered a first stage of the electronics component 110, active feedback gain 210 may be considered a second stage of the electronics component 110 and equalizer 214 may be considered a third stage of the electronics component 110. Other numbers of stages and components of stages may also be used.

EM coupler 108 may couple information (i.e., electromagnetic signals) from LUT 106 with a high pass filter-like transfer function. Stated differently, EM coupler 108 may have a high pass filter response. Integrator 206 may perform a reverse transform on the data signals received from EM coupler 108. Integrator 206 transforms the overall transfer function into a band pass filter that is broad enough to match a frequency content of the data on LUT 106. Integrator 206 may be designed or be adjusted to provide a specific filter function. As one example, the unity gain frequency of integrator 206 may equal the frequency content of the data rate of LUT 106. Accordingly, integrator 206 may provide a filter function to transform the received sampled electromagnetic signals.

Active feedback gain 210 provides an adjustable signal gain. In one embodiment, active feedback gain 210 enables electronics component 110 to compensate for overall voltage gain such that a unity gain transfer function can be achieved at analyzing device 112.

The feedback loops of offset control 208 and droop control 212 may perform offset and droop correction, respectively. In one embodiment, offset control 208 and droop control 212 may provide calibration in-situ with a test pattern whereby the transfer function is trained and adjusted to a known pattern. In another embodiment, the EM coupler 108 can be placed on a calibration point on the analyzing device 112, where a calibrated source generator provides a training pattern before the EM coupler 108 is reinstalled on the LUT 106.

Equalizer 214 may enhance high frequency content to compensate for any line loss on the LUT 106. Output driver 216 may output the recovered electromagnetic signals along output 218, which may be a high performance coaxial cable, to analyzing device 112. In one embodiment, output driver 216 may include the ability to pre-distort the output signals.

As mentioned previously, all or part of electronics component 110 may be implemented as a configuration of digital signal processing capability 114 of analyzing device 112. In one embodiment, electronics component 110 comprises a high speed amplifier with a small gain, and the remaining signal transformation is performed by digital signal processing capability 114.

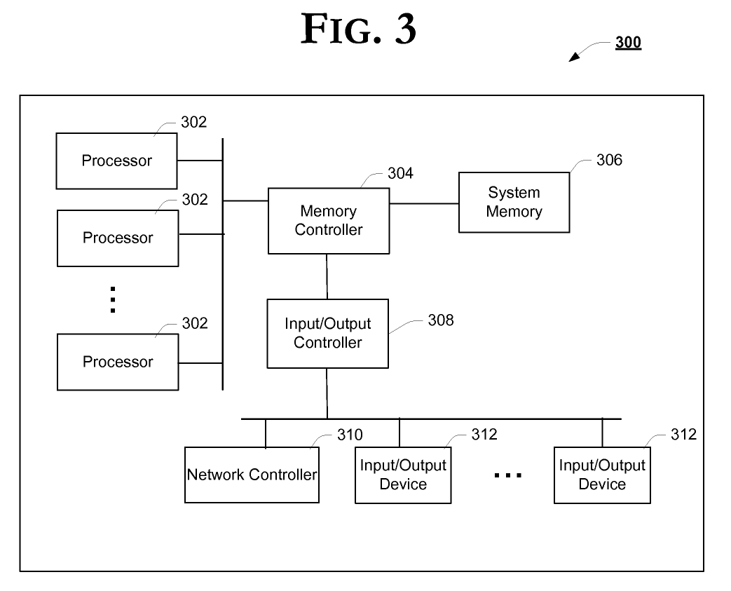

FIG. 3 is a block diagram of an example electronic appliance suitable for implementing analog validation of high speed buses using electromagnetic couplers, in accordance with one example embodiment of the invention. Electronic appliance 300 is intended to represent any of a wide variety of traditional and non-traditional electronic appliances, laptops, cell phones, wireless communication subscriber units, personal digital assistants, or any electric appliance that would benefit from the teachings of the present invention. In accordance with the illustrated example embodiment, electronic appliance 300 may include one or more of processor(s) 302, memory controller 304, system memory 306, input/output controller 308, network controller 310, and input/output device(s) 312 coupled as shown in FIG. 3. Electronic appliance 300 may include high speed connections between components that may benefit from the teachings of the present invention. In one embodiment, an EM coupler (such as EM coupler 108) and an EM receiver (such as electronics component 110) may be incorporated into a component (such as a module of system memory 306) or between components of electronic appliance 300.

Processor(s) 302 may represent any of a wide variety of control logic including, but not limited to one or more of a microprocessor, a programmable logic device (PLD), programmable logic array (PLA), application specific integrated circuit (ASIC), a microcontroller, and the like, although the present invention is not limited in this respect. In one embodiment, processors(s) 302 are Intel® compatible processors. Processor(s) 302 may have an instruction set containing a plurality of machine level instructions that may be invoked, for example by an application or operating system.

Memory controller 304 may represent any type of chipset or control logic that interfaces system memory 306 with the other components of electronic appliance 300. In one embodiment, the connection between processor(s) 302 and memory controller 304 may be a high speed/frequency serial link including. In another embodiment, memory controller 304 may be incorporated into processor(s) 302 and high speed links may directly connect processor(s) 302 with system memory 306.

System memory 306 may represent any type of memory device(s) used to store data and instructions that may have been or will be used by processor(s) 302. Typically, though the invention is not limited in this respect, system memory 306 will consist of dynamic random access memory (DRAM). In one embodiment, system memory 306 may consist of Rambus DRAM (RDRAM). In another embodiment, system memory 306 may consist of double data rate synchronous DRAM (DDRSDRAM).

Input/output (I/O) controller 308 may represent any type of chipset or control logic that interfaces I/O device(s) 312 with the other components of electronic appliance 300. In one embodiment, I/O controller 308 may be referred to as a south bridge. In another embodiment, I/O controller 308 may comply with the Peripheral Component Interconnect (PCI) Express™ Base Specification, Revision 1.0a, PCI Special Interest Group, released Apr. 15, 2003.

Network controller 310 may represent any type of device that allows electronic appliance 300 to communicate with other electronic appliances or devices. In one embodiment, network controller 310 may comply with a The Institute of Electrical and Electronics Engineers, Inc. (IEEE) 802.11b standard (approved Sep. 16, 1999, supplement to ANSI/IEEE Std 802.11, 1999 Edition). In another embodiment, network controller 310 may be an Ethernet network interface card.

Input/output (I/O) device(s) 312 may represent any type of device, peripheral or component that provides input to or processes output from electronic appliance 300.

Embodiments of the present invention may achieve a low noise performance because the integrator devices discussed above may have a relatively low bandwidth to filter input thermal noise. Further, the integrator device's high DC gain at the front of an amplifier chain may dominate any input noise. Noise performance can be further by adjusting the unity gain of the integrator device to a higher frequency.

Although embodiments of the present invention have been described with reference to a number of illustrative embodiments thereof, it should be understood that numerous other modifications and embodiments can be devised by those skilled in the art that will fall within the spirit and scope of the principles of this invention. More particularly, reasonable variations and modifications are possible in the component parts and/or arrangements of the subject combination arrangement within the scope of the foregoing disclosure, the drawings and the appended claims without departing from the spirit of the invention. In addition to variations and modifications in the component parts and/or arrangements, alternative uses will also be apparent to those skilled in the art.

What is claimed is:

1. An apparatus comprising:
an electronics component to receive sampled electromagnetic signals from an electromagnetic coupler, to amplify and recover a derivative-like output signal, and to provide recovered sampled electromagnetic signals to an oscilloscope with a unity transfer function.

2. The apparatus of claim 1, wherein the electronics component comprises an automatic gain controller to provide signals to the oscilloscope with a unity transfer function.

3. The apparatus of claim 1, wherein the electronics component comprises a sufficient bandwidth to transport the signals.

4. The apparatus of claim 1, wherein the electronics component comprises a calibration in-situ with a test pattern whereby the transfer function is trained and adjusted to a known pattern.

5. The apparatus of claim 1, wherein the electronics component comprises a pre-distorter to pre-distort the signals and transmit the signals over a high performance coaxial cable to the oscilloscope.

6. The apparatus of claim 1, wherein the electronics component comprises a memory module.

7. The apparatus of claim 1, wherein the electronics component comprises a configuration of a digital signal processing capability of the oscilloscope.

8. The apparatus of claim 7, wherein the electronics component comprises a combination of discrete components external to the oscilloscope and a configuration of a digital signal processing capability of the oscilloscope.

9. An apparatus comprising:
means for sampling signals from a line under test;
means for amplifying and recovering an output signal; and
means for transmitting a EM signal to an oscilloscope

10. The apparatus of claim 9, further comprising means for calibrating the means for amplifying, recovering and transmitting with a known pattern.

11. The apparatus of claim 9, further comprising means for validating the signals from the LUT.

12. The apparatus of claim 9, wherein the means for recovering comprises means for integrating the output signal.

13. The apparatus of claim 9, wherein the means for transmitting comprises means for automatically controlling signal gain.

14. The apparatus of claim 9, wherein the means for transmitting comprises means for pre-distorting the EM signal.

15. A system comprising:
an electromagnetic coupler to receive electromagnetic signals based on data on a link;
an electronics component to receive the electromagnetic signals from the electromagnetic coupler and to amplify and recover a derivative-like output signal, the electronics component including an automatic gain controller to provide signals to an analyzing device with a unity transfer function; and
the analyzing device to receive the recovered electromagnetic signals to allow data signals corresponding to the recovered electromagnetic signals to be validated.

16. The system of claim 15, wherein the electronics component further comprises a calibration in-situ with a test pattern whereby the transfer function is trained and adjusted to a known pattern.

17. The system of claim 15, wherein the electronics component further comprises a pre-distorter to pre-distort the signals.

18. The system of claim 15, wherein the electronics component comprises a configuration of a digital signal processing capability of the analyzing device.

19. The system of claim 15, wherein the electronics component comprises a combination of discrete components external to the analyzing device and a configuration of a digital signal processing capability of the analyzing device.

20. The system of claim 15, wherein the analyzing device comprises a filter to remove jitter caused by the electronics component.
